(19) United States
(12) Patent Application Publication
(10) Pub. No.: US 2025/0289982 A1
(43) Pub. Date: Sep. 18, 2025

(54) RESIN COMPOSITION, CURED RESIN PRODUCT, AND DISPLAY DEVICE INCLUDING THE SAME

(71) Applicant: Samsung Display Co., Ltd., Yongin-si (KR)

(72) Inventor: Tetsuya Fujiwara, Yokohama (JP)

(73) Assignee: Samsung Display Co., Ltd., Yongin-si (KR)

(21) Appl. No.: 18/894,644

(22) Filed: Sep. 24, 2024

(30) Foreign Application Priority Data
Mar. 12, 2024 (KR) 10-2024-0034717

(51) Int. Cl. C09J 7/38; H05K 5/03

(52) U.S. Cl. CPC C09J 7/385; H05K 5/03; C09J 2203/326; C09J 2301/416

(57) ABSTRACT

A resin composition includes about 1 part by weight to about 10 parts by weight of a urethane (meth)acrylate oligomer having two (meth)acrylic groups, about 80 parts by weight to about 95 parts by weight of a mono-functional acrylate monomer, about 0.1 parts by weight to about 1 part by weight of a (meth)acrylate monomer having two (meth)acrylic groups, and about 1 part by weight to about 5 parts by weight of a hydrogen abstraction-type photoinitiator. Some of the mono-functional acrylate monomer include a cyclopentenyl group. The resin composition may have a viscosity of greater than or equal to about 5 mPas and less than 20 mPas at 30° C.

### CROSS-REFERENCE TO RELATED APPLICATION(S)

This application claims priority to and benefits of Korean Patent Application No. 10-2024-0034717 under 35 U.S.C. § 119, filed on Mar. 12, 2024, in the Korean Intellectual Property Office (KIPO), the entire contents of which are incorporated herein by reference.

### BACKGROUND

### 1. Technical Field

One or more embodiments relate to a resin composition, a cured resin product, and a display device including the same.

### 2. Description of the Related Art

Optically clear adhesives (OCAs), which are adhesive sheets, have been used as adhesives for display devices. However, as the shapes of display devices diversify, the development of optically clear resins (OCRs), which are liquid adhesives, is in progress. In particular, recently, due to the thinning of display devices, an inkjet process for optically clear resins (OCRs) is required, and to this end, low viscosity of optically clear resins (OCRs) is needed. In case that low viscosity optically clear resins (OCRs) are photocured, it is desirable to maintain physical properties, such as adhesive properties, of the cured product.

### SUMMARY

One or more embodiments include a resin composition that enables a stable inkjet process at room temperature, has high adhesion even after photocuring in an oxygen atmosphere, and is applicable to display devices of various shapes.

Additional aspects will be set forth in part in the description which follows and, in part, will be apparent from the description, or may be learned by practice of the presented embodiments of the disclosure.

According to one or more embodiments, a resin composition may include
about 1 part by weight to about 10 parts by weight of a urethane (meth)acrylate oligomer having two (meth)acrylic groups (A),
about 80 parts by weight to about 95 parts by weight of a mono-functional acrylate monomer (B),
about 0.1 parts by weight to about 1 part by weight of a (meth)acrylate monomer having two (meth)acrylic groups (C), and
about 1 part by weight to about 5 parts by weight of a hydrogen abstraction-type photoinitiator (D).

Some of the mono-functional acrylate monomers (B) may have a dicyclopentenyl group.

The parts by weight may be based on a total weight of the resin composition.

The resin composition may have a viscosity of greater than or equal to about 5 mPas and less than 20 mPas at 30° C.

According to an embodiment, a weight average molecular weight (Mw) of the urethane (meth)acrylate oligomer having two (meth)acrylic groups may be greater than or equal to about 10,000 and less than 40,000.

According to an embodiment, the resin composition may include two or more types of the urethane (meth)acrylate oligomer having two (meth)acrylic groups.

According to an embodiment, a molecular weight difference between the two or more types of urethane (meth)acrylate oligomer having two (meth)acrylic groups may be in a range of about 5,000 to about 30,000.

According to an embodiment, a weight average molecular weight (Mw) of the mono-functional acrylate monomer may be less than or equal to about 500.

According to an embodiment, the resin composition may include two or more types of the mono-functional acrylate monomer.

According to an embodiment, an amount of monomers having the dicyclopentenyl group from among the mono-functional acrylate monomer may be in a range of about 20 parts by weight to about 40 parts by weight, based on the total weight of the resin composition.

According to an embodiment, a weight average molecular weight (Mw) of the (meth)acrylate monomer having two (meth)acrylic groups may be less than or equal to about 500.

According to an embodiment, the resin composition may not include a solvent.

According to an embodiment, the resin composition may further include about 1 part by weight to about 5 parts by weight of a tertiary amine group-containing hydrogen donor.

According to an embodiment, the urethane (meth)acrylate oligomer having two (meth)acrylic groups may include UV-3700B (Mitsubishi Chemical), UV-3300B (Mitsubishi Chemical), UN-7700 (Negami Industry), UF-C051 (Kyoeisha Chemical), CN9021NS (SARTOMER), KRM9465 (Daicel-Allnex), EBECRYL8411 (Daicel-Allnex), or a combination thereof.

According to an embodiment, the mono-functional acrylate monomer may include isodecyl acrylate, isobornyl acrylate, tetrahydrofurfuryl (meth)acrylate, dicyclopentenyl oxyethyl acrylate, dicyclopentenyl oxyethyl (meth)acrylate, 2-ethylhexyl acrylate, 4-hydroxybutyl acrylate, 2-methyl-2-ethyl-1,3-dioxolane-4-ylmethyl acrylate, butyl acrylate, lauryl acrylate, 2-ethyl hexyl diglycol acrylate, mono(2-acryloyloxyethyl) succinate, tert-butyl acrylate, n-octyl acrylate, cyclohexyl acrylate, or a combination thereof.

According to an embodiment, the (meth)acrylate monomer having two (meth)acrylic groups may include 1,9-nonanedioldiacrylate, 1,4-butanedioldi (meth)acrylate, 1,3-butyleneglycoldi (meth)acrylate, 1,6-hexanedioldi (meth)acrylate, 1,8-octanedioldi (meth)acrylate, 1,9-octanedioldiacrylate, 1,12-dodecanedioldi (meth)acrylate, neopentylglycoldi (meth)acrylate, dicyclopentanyldi (meth)acrylate, cyclohexane-1,4-methanoldi (meth)acrylate, tricyclodecanedimethanoldi (meth)acrylate, dicyclopentanedimethyloldi (meth)acrylate, neopentylglycol modified trimethylpropanedi (meth)acrylate, adamantanedi (meth)acrylate, trimethylolpropanetri (meth)acrylate, or a combination thereof.

According to an embodiment, a storage modulus at 25° C. of a cured resin product produced after photocuring of the resin composition may be greater than or equal to about 0.05 MPa and less than 0.5 MPa.

According to an embodiment, a change in yellow index (ΔYI) of a cured resin product produced after photocuring of the resin composition, before and after a light resistance test based on a DIN75220 standard, may be less than or equal to about 1.

According to an embodiment, a 180° peel strength at 25° C. of a laminate obtained by bonding a polyethylene telephthalate (PET) film and soda lime glass by using the resin composition may be in a range of about 2500 (gf/25 mm) to about 5000 (gf/25 mm).

According to one or more embodiments, provided is
a cured resin product may be manufactured by photocuring the resin composition.

The cured resin product may be an adhesive member.

According to one or more embodiments, a display device may include
a display panel,
a cover window disposed on the display panel, and
a photocured adhesive layer arranged between the display panel and the cover window, wherein
the photocured adhesive layer may include the cured resin product described above.

The display device may be a foldable display device.

### BRIEF DESCRIPTION OF THE DRAWINGS

The above and other aspects, features, and advantages of certain embodiments of the disclosure will be more apparent from the following description taken in conjunction with the accompanying drawings, in which:

FIGS. 1 and 2 are perspective views schematically showing part of a display device according to an embodiment;

FIG. 3A is a schematic cross-sectional view schematically showing part of a display device according to an embodiment; and

FIG. 3B is a schematic cross-sectional view schematically showing part of a display device according to another embodiment.

### DETAILED DESCRIPTION OF THE EMBODIMENTS

Since the disclosure can be modified in various ways and can have various embodiments, specific embodiments will be illustrated and described in detail in the detailed description. The effects and features of the disclosure and methods for achieving the same will become clear by referring to the embodiments described in detail below. The disclosure may, however, be embodied in many different forms and should not be construed as limited to the embodiments set forth herein.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements.

In this specification, the x-axis, y-axis, and z-axis are not limited to the three axes in the Cartesian coordinate system, but can be interpreted in a broad sense including the same. For example, the x-axis, y-axis, and z-axis may refer to those orthogonal to each other, or may refer to those in different directions that are not orthogonal to each other.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within +30%, 20%, 10%, 5% of the stated value.

In the specification and the claims, the phrase “at least one of” is intended to include the meaning of “at least one selected from the group of” for the purpose of its meaning and interpretation. For example, “at least one of A and B” may be understood to mean “A, B, or A and B.” In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

The term “a (meth)acrylic group” as used herein may be a methacrylic group or an acrylic group. Similarly, the term “(meth)acrylate” as used herein may be methacrylate or acrylate.

A resin composition according to an embodiment may include a urethane (meth)acrylate oligomer having two (meth)acrylic groups (A), a mono-functional acrylate monomer (B), and a (meth)acrylate monomer having two (meth)acrylic groups (C), and/or a hydrogen abstraction-type photoinitiator (D).

In an embodiment, based on 100 parts by weight of the resin composition, the urethane (meth)acrylate oligomer having two (meth)acrylic groups (A) may be included in an amount in a range of about 1 part by weight to about 10 parts by weight, the mono-functional acrylate monomer (B) may be included in an amount in a range of about 80 parts by weight to about 95 parts by weight, the (meth)acrylate monomer having two (meth)acrylic groups (C) may be included in an amount in a range of about 0.1 parts by weight to about 1 part by weight, and the photoinitiator (D) may be included in an amount in a range of about 1 part by weight to about 5 parts by weight.

In an embodiment, the urethane (meth)acrylate oligomer having two (meth)acrylic groups (A), the mono-functional acrylate monomer (B), and the (meth)acrylate monomer having two (meth)acrylic groups. (C) may each independently include two or more types thereof. For example, the urethane (meth)acrylate oligomer (A) may include two or three types of urethane (meth)acrylate having two (meth)acrylic groups. For example, the mono-functional acrylate monomer (B) may include 2 to 5 types, or 3 or 4 types of mono-functional acrylate monomers.

In an embodiment, the urethane (meth)acrylate oligomer having two (meth)acrylic groups (A) may have a weight average molecular weight (Mw) in a range of about 10,000 to about 40,000. For example, the urethane (meth)acrylate oligomer having two (meth)acrylic groups (A) may include two types of urethane (meth)acrylate oligomers having two (meth)acrylic groups, where a molecular weight difference between the two types of urethane (meth)acrylate oligomers having the two (meth)acrylic groups may be in a range of about 5,000 to about 30,000. For example, the molecular weight difference between the two types of urethane (meth)acrylate oligomers having the two (meth)acrylic groups may be in a range of about 7,000 to about 25,000. In an embodiment, the mono-functional acrylate monomer (B) may have a weight average molecular weight (Mw) of less than or equal to about 500. For example, the mono-functional acrylate monomer (B) may have a weight average molecular weight (Mw) in a range of about 200 to about 500. For example, the mono-functional acrylate monomer (B) may have a weight average molecular weight (Mw) in a range about 200 to about 400. In an embodiment, the (meth)acrylate monomer having two (meth)acrylic groups (C) may have a weight average molecular weight (Mw) of less than or equal to about 500. For example, the (meth)acrylate monomer (C) having the two (meth)acrylic groups may have a weight average molecular weight (Mw) in a range of about 100 to about 500. For example, the (meth)acrylate monomer (C) having the two (meth)acrylic groups may have a weight average molecular weight (Mw) in a range of about 200 to about 400.

Some of the mono-functional acrylate monomers (B) may include a dicyclopentenyl group. For example, the mono-functional acrylate monomer (B) may include four types of mono-functional acrylate monomers, and one or two types of mono-functional acrylate monomers may have a dicyclopentenyl group. In an embodiment, an amount of the mono-functional acrylate monomer (B) having a dicyclopentenyl group may be in a range of about 20 parts by weight to about 40 parts by weight based on 100 parts by weight of the resin composition. In case that some of the mono-functional acrylate monomers (B) having a dicyclopentenyl group have this amount range, yellowing of the resin composition upon ultraviolet (UV) radiation and yellowing of the cured resin product over time due to UV rays may be prevented or reduced.

The resin composition may be a solvent-free resin composition that does not contain a solvent.

The resin composition may have a viscosity in a range of about 5 mPa·s to about 20 mPas at 30° C. In case that the viscosity of the resin composition is less than 5 mPa·s, deviations may occur in the inkjet discharge amount and film thickness after application. In case that the viscosity of the resin composition is 20 greater than mPa·s, inkjet ejection defects and nozzle clogging may occur.

In an embodiment, the resin composition may further include about 1 part by weight to about 5 parts by weight of a tertiary amine group-containing hydrogen donor (E). The tertiary amine group-containing hydrogen donor (E) may promote initiate photopolymerization caused by the hydrogen abstraction-type photoinitiator (D).

The urethane (meth)acrylate oligomer having two (meth)acrylic groups (A) may be an oligomer containing two (meth)acrylic groups each having a urethane bond in one unit. The urethane (meth)acrylate oligomer may include at least one of acrylate having a urethane bond, urethane acrylate having a polycarbonate skeleton, and urethane acrylate having a polyether skeleton. The urethane (meth)acrylate oligomer having two (meth)acrylic groups (A) may include, for example, UV-3700B (Mitsubishi Chemical), UV-3300B (Mitsubishi Chemical), UN-7700 (Negami Industry), UF-C051 (Kyoeisha Chemical), CN9021NS (SARTOMER), KRM9465 (Daicel-Allnex), EBECRYL8411 (Daicel-Allnex), or a combination thereof, but the disclosure is not limited thereto.

The mono-functional acrylate monomer (B) may include alicyclic (meth)acrylate, alkyl (meth)acrylate, a hydroxy group-containing (meth)acrylate, or a combination thereof. For example, the mono-functional acrylate monomer (B) may include isodecyl acrylate, isobornyl acrylate, tetrahydrofurfuryl (meth)acrylate, dicyclopentenyl oxyethyl acrylate, dicyclopentenyl oxyethyl (meth)acrylate, 2-ethylhexyl acrylate, 4-hydroxybutyl acrylate, 2-methyl-2-ethyl-1,3-dioxolane-4-ylmethyl acrylate, butyl acrylate, lauryl acrylate, 2-ethyl hexyl diglycol acrylate, mono(2-acryloyloxyethyl) succinate, tert-butyl acrylate, n-octyl acrylate, cyclohexyl acrylate, or a combination thereof, but the disclosure is not limited thereto.

The (meth)acrylate monomer having two (meth)acrylic groups (C) may include 1,9-nonanedioldiacrylate, 1,4-butanedioldi (meth)acrylate, 1,3-butyleneglycoldi (meth)acrylate, 1,6-hexanedioldi (meth)acrylate, 1,8-octanedioldi (meth)acrylate, 1,9-octanedioldiacrylate, 1,12-dodecanedioldi (meth)acrylate, neopentylglycoldi (meth)acrylate, cyclohexane-1,4-methanoldi (meth)acrylate, dicyclopentanyldi (meth)acrylate, tricyclodecanedimethanoldi (meth)acrylate, dicyclopentanedimethyloldi (meth)acrylate, neopentylglycol modified trimethylpropanedi (meth)acrylate, adamantanedi (meth)acrylate, trimethylolpropanetri (meth)acrylate, or a combination thereof, but the disclosure is not limited thereto.

The hydrogen abstraction-type photoinitiator (D) may include, for example, 1-[4-(4-benzoyl phenylsulfanyl)phenyl]-2-methyl-2-(4-methylphenylsulfonyl) propan-1-one, benzophenone, benzoylbenzoate, methyl benzoylbenzoate, 4-phenylbenzophenone, hydroxybenzophenone, 3,3′-dimethyl-4-methoxybenzophenone, 2,4,6-trimethylbenzophenone, 4-methylbenzophenone, thioksanthone, 2-chlorthioxanthone, 2-methylthioxanthone, 2,4-dimethylthioxanthone, isopropylthioxanthone, camphorquinone, 3,3′,4,4′-tetra(t-butylfer)oxycarbonyl)benzophenone, 1-[4-(4-benzoylphenylthio)phenyl]-2-tosyl-2-methyl-1-propanone, 2-ethylhexyl 2-([1,1′-biphenyl]-4-ylcarbonyl)benzoate, ketocoumarin, or a combination thereof, but the disclosure is not limited thereto.

The tertiary amine group-containing hydrogen donor (E) may include ethyl-4-(dimethylamino)-benzoate, poly(ethylene glycol) bis(p-dimethylaminobenzoate), (methylimino) diethylene bis [4-(dimethylamino)benzoate], 1,4-bis(aminopropyl) piperazine, tetramethylethylenediamine, or a combination thereof, but the disclosure is not limited thereto.

In an embodiment, the resin composition may further include an additive, such as a photosensitizer, a photopolymerization accelerator, a curing catalyst, a flame retardant, an anti-flow agent, an antioxidant, an anti-aging agent, an ultraviolet absorber, a pigment, a dye, a filler, and a diluent, in such amounts that do not damage the physical properties of the resin composition.

In an embodiment, a storage modulus of the cured resin product produced after photocuring the resin composition at 25° C. may be in a range of about 0.05 MPa to about MPa. In case that the cured resin product has this range of storage modulus, adhesive and cohesive forces may be simultaneously obtained with excellent adhesive performance.

In an embodiment, the cured resin product produced after photocuring the resin composition may have a change in yellow index (ΔYI) of less than or equal to about 1 before and after a light resistance test based on the DIN75220 standard. Yellow index (YI) indicates the degree of separation from white to yellow direction on the CIE chromaticity diagram. The amount of change in yellow index (ΔYI) may be an indicator that can evaluate the degree of deterioration of a cured resin product material by ultraviolet rays.

The amount of change in yellow index (ΔYI) may be expressed by Equation 1.

ΔYI=YI(after light resistance test)−YI(before light resistance test) [Equation 1]

In an embodiment, the 180° peel strength at 25° C. of a laminate obtained by bonding a polyethylene telephthalate (PET) film and soda lime glass using the resin composition may be greater than or equal to about 2500 (gf/25 mm). For example, the 180° peel strength at 25° C. of the laminate may be in a range of about 2500 to about 4000. For example, the 180° peel strength at 25° C. of the laminate may be in a range of about 2600 to about 3600.

The resin compositions according to the embodiments may be precisely processed through inkjet printing at room temperature. The resin compositions according to present embodiments may not be significantly affected by oxygen inhibition, which inhibits the polymerization reaction by oxygen when photocured in an oxygen atmosphere, so that the resin composition can be readily photocured, and may have high light resistance, excellent adhesion, and cohesiveness after photocuring.

A cured resin product according to an embodiment may be manufactured by radiating light on the resin composition according to the embodiments under atmospheric condition. The light radiation may be, for example, UV radiation. In an embodiment, the cured resin product may have a storage modulus in a range of about 0.05 MPa to about 0.5 MPa at 25° C. In an embodiment, an amount of change in yellow index (ΔYI) before and after the light resistance test based on the DIN75220 standard for the cured resin product may be less than or equal to about 1. An 180° peel strength at 25° C. of the laminate manufactured by applying the resin composition between a polyethylene telephthalate (PET) film and soda lime glass and radiating light thereon may be, for example, in a range of about 2500 (gf/25 mm) to about 4000 (gf/25 mm). For example, the 180° peel strength at 25° C. of the laminate manufactured by applying the resin composition between a polyethylene telephthalate (PET) film and soda lime glass and radiating light thereon may be, for example, in a range of about 2600 (gf/25 mm) to about 3600 (gf/25 mm).

In an embodiment, the cured resin product may be an adhesive member. The adhesive member may be applied to a display device.

A display device according to an embodiment may include a display panel, a cover window disposed on the display panel, and a photocured adhesive layer disposed between the display panel and the cover window. The photocured adhesive layer may include a cured resin product according to the embodiments.

A display device according to an embodiment may be a foldable display device. A display device according to an embodiment may be a display device including a bending area. A display device according to an embodiment may be a rollable display device. A display device according to an embodiment may be a display device that has a curve in some areas.

The resin composition according to the embodiments may be applied to a display device having various shapes such as folded, bent, rolled, and curved by a method such as inkjet printing to stably adhere members, such as a display panel and a cover window, to each other.

Hereinafter, embodiments of the disclosure will be described in detail with reference to the accompanying drawings. The same or corresponding components will be denoted by the same reference numerals, and thus redundant description thereof will be omitted.

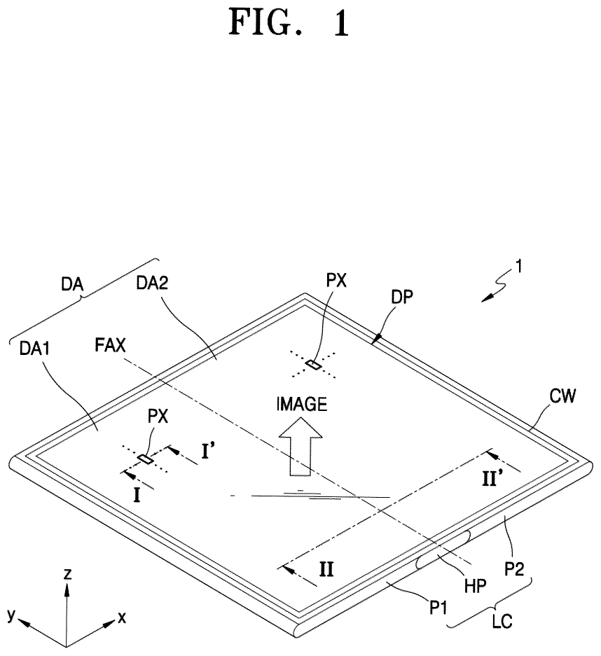

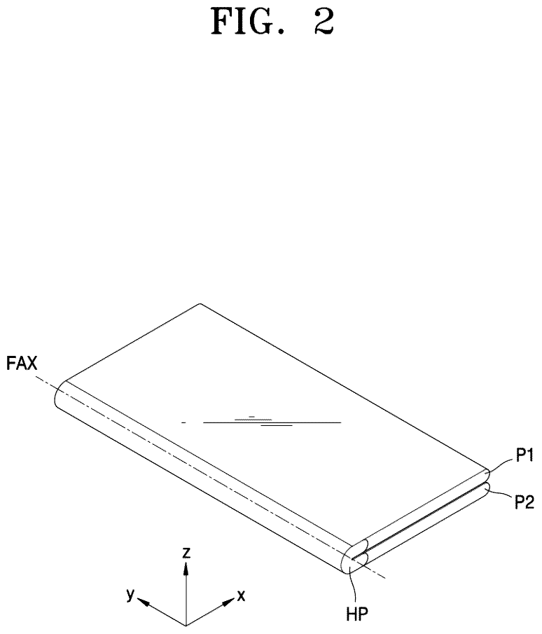

FIGS. 1 and 2 are perspective views schematically showing a part of a display device 1 according to an embodiment. In detail, FIG. 1 shows the display device 1 in an unfolded state, and FIG. 2 shows the display device 1 in a folded state.

Referring to FIGS. 1 and 2, the display device 1 may include a lower cover LC, a display panel DP, and a cover window CW.

The lower cover LC may include a first part P1 and a second part P2 each supporting the display panel DP. The lower cover LC may be foldable around a folding axis FAX defined between the first part P1 and the second part P2. In an embodiment, the lower cover LC may further include a hinge part HP, and the hinge part HP may be provided between the first part P1 and the second part P2.

The display panel DP may include a display area DA. The display panel DP may provide an image through an array of multiple pixels PX arranged in the display area DA. Each of pixels PX may be defined as a light-emitting area where light is emitted by a light-emitting element electrically connected to a pixel circuit. In an embodiment, each of the pixels PX may emit red, green, or blue light. In another embodiment, each of the pixels PX may emit red, green, blue, or white light.

The light-emitting element included in the display panel DP may include organic light-emitting diodes, inorganic light-emitting diodes, micro light-emitting diodes, and/or quantum dot light-emitting diodes. For convenience of explanation, the following description will focus on an embodiment that the light-emitting element provided by the display panel DP includes an organic light-emitting diode, but the disclosure is not limited thereto and the disclosure may be applicable even to embodiments including other light-emitting elements.

The display area DA may include a first display area DA1 and a second display area DA2 arranged on opposite sides around the folding axis FAX that crosses the display area DA. The first display area DA1 and the second display area DA2 may be located on the first part P1 and the second part P2 of the lower cover LC, respectively. The display panel DP may provide a first image and a second image by using light emitted from the pixels PX disposed in the first display area DA1 and the second display area DA2. In an embodiment, the first image and the second image may be parts of an image provided through the display area DA of the display panel DP. In another embodiment, the display panel DP may provide a first image and a second image that are independent of each other.

The display panel DP may be foldable around the folding axis FAX. In case that the display panel DP is folded, the first display area DA1 and the second display area DA2 of the display panel DP may face each other.

FIGS. 1 and 2 show an embodiment that the folding axis FAX extends in a y direction, but the disclosure is not limited thereto. In an embodiment, the folding axis FAX may extend in an x-direction intersecting the y-direction. In some embodiments, the folding axis FAX on an xy plane may extend in a direction intersecting the x direction and the y direction.

FIGS. 1 and 2 show an embodiment that there is only one folding axis FAX, but the disclosure is not limited thereto. In an embodiment, the display panel DP may be foldable multiple times around multiple folding axes FAX crossing the display area DA.

The cover window CW may be disposed on the display panel DP to cover the display panel DP. The cover window CW may be foldable or bendable in case that an external force is applied without causing cracks. In case that the display panel DP is folded around the folding axis FAX, the cover window CW may also be folded together.

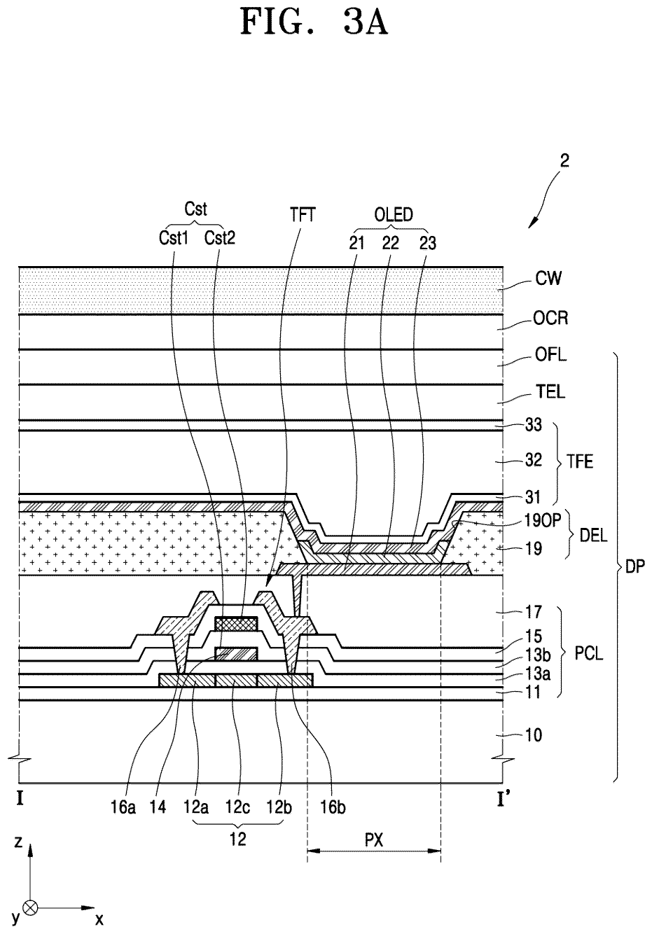

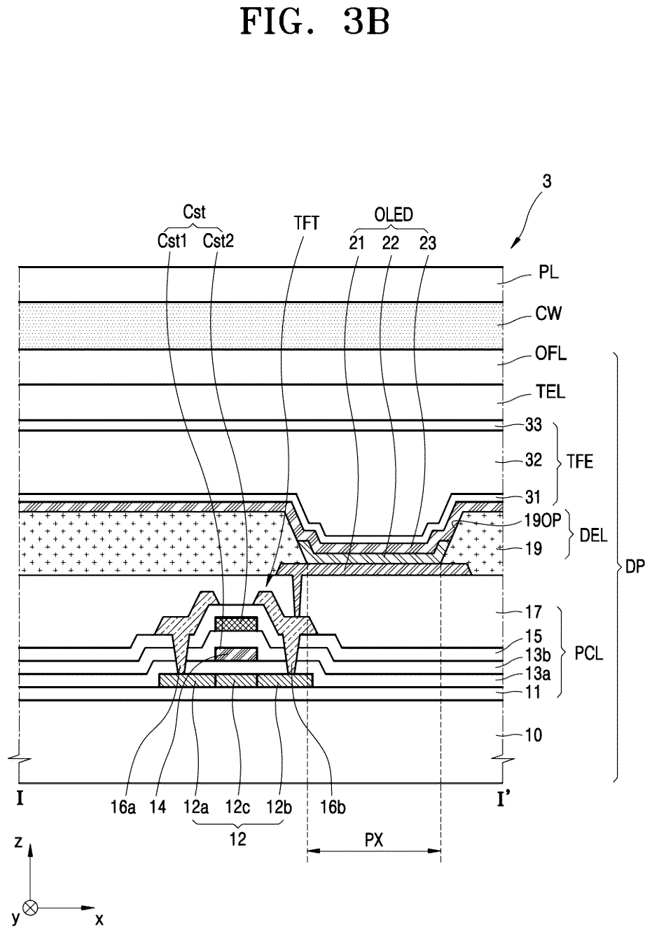

FIG. 3A is a schematic cross-sectional view schematically showing a portion of the display device 2 according to an embodiment, and FIG. 3B is a schematic cross-sectional view schematically showing a part of the display device 3 according to another embodiment. FIGS. 3A and 3B may correspond to cross-sectional views of the display device taken along line I-l′ of FIG. 1.

Referring to FIGS. 3A and 3B, the display panel DP may have a stacked structure including a substrate 10, a pixel circuit layer PCL, a display element layer DEL, a thin film encapsulation layer TFE, a touch electrode layer TEL, and an optical functional layer OFL.

The substrate 10 may include glass or a polymer resin. In an embodiment, the polymer resin may include at least one of polyether sulfone, polyarylate, polyether imide, polyethylene naphthalate, polyethylene terephthalate, polyphenylene sulfide, polyimide, polycarbonate, cellulose triacetate, and cellulose acetate propionate.

A pixel circuit layer PCL may be disposed on the substrate 10. Referring to FIGS. 3A and 3B, the pixel circuit layer PCL may include a thin film transistor TFT, and a buffer layer 11, a first insulating layer 13a, a second insulating layer 13b, a third insulating layer 15, and a planarization layer 17, which are disposed below or/and above the components of the thin film transistor TFT.

The buffer layer 11 may reduce or block the infiltration of foreign materials, moisture, or external air from the lower part of the substrate 10, and provide a flat surface on the substrate 10. The buffer layer 11 may include an inorganic insulating material such as silicon nitride, silicon oxynitride, and silicon oxide, and may be a single layer or multilayer containing the inorganic insulating material.

The thin film transistor TFT on the buffer layer 11 may include a semiconductor layer 12, and the semiconductor layer 12 may include polysilicon. In some embodiments, the semiconductor layer 12 may include amorphous silicon, an oxide semiconductor, an organic semiconductor, etc. The semiconductor layer 12 may include a channel region 12c and a drain region 12a and a source region 12b disposed on opposite sides of the channel region 12c, respectively. A gate electrode 14 may overlap the channel region 12c in a plan view.

The gate electrode 14 may include a low-resistance metal material. The gate electrode 14 may include a conductive material such as molybdenum (Mo), aluminum (Al), copper (Cu), titanium (Ti), etc., and may be formed as a multilayer or single layer containing at least one of the conductive materials described above.

The first insulating layer 13a may be positioned between the semiconductor layer 12 and the gate electrode 14. The first insulating layer 13a may include an inorganic insulating material such as silicon oxide (SiO₂), silicon nitride (SiN_{X}), silicon oxynitride (SiON), aluminum oxide (Al₂O₃), titanium oxide (TiO₂), tantalum oxide (Ta₂O₅), hafnium oxide (HfO₂), or zinc oxide (ZnO).

The second insulating layer 13b may cover the gate electrode 14. The second insulating layer 13b may include an inorganic insulating material such as silicon oxide (SiO₂), silicon nitride (SiN_{X}), silicon oxynitride (SiON), aluminum oxide (Al₂O₃), titanium oxide (TiO₂), tantalum oxide (Ta₂O₅), hafnium oxide (HfO₂), or zinc oxide (ZnO).

An upper electrode Cst2 of the storage capacitor Cst may be disposed on the second insulating layer 13b. The upper electrode Cst2 may at least partially overlap the gate electrode 14 in a plan view disposed below the upper electrode Cst2. The gate electrode 14 and the upper electrode Cst2 that overlap each other, with the second insulating layer 13b between the gate electrode 14 and the upper electrode Cst2, may form a storage capacitor Cst. For example, the gate electrode 14 may function as a lower electrode Cst1 of the storage capacitor Cst.

In an embodiment, the storage capacitor Cst and the thin film transistor TFT may be overlapped each other in a plan view. In another embodiment, the storage capacitor Cst may not overlap the thin film transistor TFT. For example, the lower electrode Cst1 of the storage capacitor Cst may be formed, as a separate component with respect to the gate electrode 14, to be spaced apart from the gate electrode 14 in a plan view.

The upper electrode Cst2 may include aluminum (Al), platinum (Pt), palladium (Pd), silver (Ag), magnesium (Mg), gold (Au), nickel (Ni), neodymium (Nd), and iridium (Ir), chromium (Cr), calcium (Ca), molybdenum (Mo), titanium (Ti), tungsten (W), and/or copper (Cu), and may be a single layer or multilayer of these materials.

The third insulating layer 15 may cover the upper electrode Cst2. The third insulating layer 15 may include an inorganic insulating material such as silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnO). The third insulating layer 15 may be a single layer or multilayer comprising at least one of these inorganic insulating materials.

The drain electrode 16a and the source electrode 16b may each be located on the third insulating layer 15. The drain electrode 16a and the source electrode 16b may be connected to the drain region 12a and the source region 12b through contact holes in the insulating layers below the drain electrode 16a and the source electrode 16b, respectively. The drain electrode 16a and the source electrode 16b may include a material with good conductivity. The drain electrode 16a and the source electrode 16b may include a conductive material such as molybdenum (Mo), aluminum (Al), copper (Cu), titanium (Ti), etc., and may be formed as a multilayer or single layer. In an embodiment, the drain electrode 16a and the source electrode 16b may have a multilayer structure of Ti/Al/Ti.

The planarization layer 17 may include an organic insulating material such as a general-purpose polymer such as polymethylmethacrylate (PMMA) or polystyrene (PS), or a polymer derivative having a phenol-based group, an acryl-based polymer, an imide-based polymer, an arylether polymer, an amide-based polymer, a fluorine-based polymer, a p-xylene-based polymer, a vinyl alcohol-based polymer, and a blend thereof.

A display element layer DEL may be disposed on the pixel circuit layer PCL having the structure described above. The display element layer DEL may include an organic light-emitting diode OLED as a light-emitting device, and the organic light-emitting diode OLED may have a stacked structure of a first electrode 21, an emission layer 22, and a second electrode 23. The first electrode 21 of the organic light-emitting diode OLED may be electrically connected to the thin film transistor TFT through a contact hole defined in the planarization layer 17.

The first electrode 21 may include a conductive oxide, such as indium tin oxide (ITO), indium zinc oxide (IZO), zinc oxide (ZnO), indium oxide (In₂O₃), indium gallium oxide (IGO), or aluminum zinc oxide (AZO). In an embodiment, the first electrode 21 may include a reflective film including silver (Ag), magnesium (Mg), aluminum (Al), platinum (Pt), palladium (Pd), gold (Au), nickel (Ni), neodymium (Nd), iridium (Ir), chromium (Cr), or a compound thereof. In some embodiments, the first electrode 21 may further include a film including ITO, IZO, ZnO, or In₂O₃ above/below the reflective film.

A pixel defining layer 19 having an opening 19OP that exposes at least a portion of the first electrode 21 may be disposed on the first electrode 21. The pixel defining layer 19 may include an organic insulating material and/or an inorganic insulating material. The opening 19OP may define a light-emitting area of the light emitted from the organic light-emitting diode OLED. For example, the size/width of the opening 19OP may correspond to the size/width of the light-emitting area in a plan view. Accordingly, the size and/or width of a pixel PX may depend on the size and/or width of the opening 19OP of the pixel defining layer 19.

The emission layer 22 may be disposed in the opening 19OP of the pixel defining layer 19. The emission layer 22 may include a polymer organic material or a low-molecular organic material that emits light of a color. In some embodiments, the emission layer 22 may include an inorganic light-emitting material or quantum dots.

Although not shown in FIGS. 3A and 3B, a first functional layer and a second functional layer may be disposed below and above the emission layer 22, respectively. For example, the first functional layer may include a hole transport layer (HTL), or a HTL and a hole injection layer (HIL). The second functional layer may include an electron transport layer (ETL) and/or an electron injection layer (EIL). However, the disclosure is not limited thereto. The first functional layer and the second functional layer may be selectively disposed above and below the emission layer 22, respectively.

Like the second electrode 23 which will be described below, the first functional layer and/or the second functional layer may each be a common layer formed to entirely cover the substrate 10.

The second electrode 23 may be disposed on the first electrode 21 and may overlap the first electrode 21 in a plan view. The second electrode 23 may include a conductive material with a low work function. For example, the second electrode 23 may include a (semi) transparent layer including silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca), or an alloy thereof. In some embodiments, the second electrode 23 may further include a layer including ITO, IZO, ZnO, or In₂O₃ on the (semi) transparent layer including these materials. The second electrode 23 may be formed integrally to entirely cover the substrate 10.

An encapsulation member may be disposed on the display element layer DEL. In an embodiment, the encapsulation member may be provided as a thin film encapsulation layer TFE. The thin film encapsulation layer TFE may be disposed on the display element layer DEL and cover the display element layer DEL. The thin film encapsulation layer TFE may include at least one inorganic encapsulation layer and at least one organic encapsulation layer. In an embodiment, the thin film encapsulation layer TFE may include a first inorganic encapsulation layer 31, an organic encapsulation layer 32, and a second inorganic encapsulation layer 33 which are sequentially stacked. In another embodiment, the encapsulation member may be provided as an encapsulation substrate.

The first inorganic encapsulation layer 31 and the second inorganic encapsulation layer 33 may include at least one inorganic material such as aluminum oxide, titanium oxide, tantalum oxide, hafnium oxide, zinc oxide, silicon oxide, silicon nitride, and silicon oxynitride. The organic encapsulation layer 32 may include a polymer-based material. The polymer-based material may include an acrylic resin, an epoxy resin, polyimide, and polyethylene. In an embodiment, the organic encapsulation layer 32 may include acrylate. The organic encapsulation layer 32 may be formed by curing a monomer or applying a polymer.

A touch electrode layer TEL including touch electrodes may be disposed on the thin film encapsulation layer TFE, and an optical functional layer OFL may be disposed on the touch electrode layer TEL. The touch electrode layer TEL may obtain coordinate information according to an external input, for example, a touch event. The optical functional layer OFL may reduce the reflectance of light (external light) incident from the outside toward the display device 1 and improve the color purity of light emitted from the display device 1.

In an embodiment, the optical functional layer OFL may include a phase retarder and/or a polarizer. The phase retarder may be a film type or a liquid crystal coating type, and may include a λ/2 phase retarder and/or a λ/4 phase retarder. The polarizer may also be a film type or a liquid crystal coating type. The film type of the polarizer may include a stretched synthetic resin film, and the liquid crystal coating type of the polarizer may include liquid crystals arranged in an arrangement. The phase retarder and the polarizer may further include a protective film.

In an embodiment, the optical functional layer OFL may include a destructive interference structure. The destructive interference structure may include a first reflective layer and a second reflective layer disposed on different layers. The first reflected light and the second reflected light reflected from the first reflective layer and the second reflective layer, respectively, may interfere destructively, and thus the external light reflectance may be reduced.

An adhesive member may be disposed between the touch electrode layer TEL and the optical functional layer OFL. The adhesive member may be a photocured adhesive layer (not shown) including the resin composition.

A cover window CW may be placed on the display panel DP. The cover window CW may be adhered onto the display panel DP by using an adhesive member. The adhesive member may be a photocured adhesive layer (not shown) including the resin composition as described above.

The cover window CW may have a high transmittance to transmit light emitted from the display panel DP. In an embodiment, the transmittance of the cover window CW may be greater than or equal to about 85%, and the transmission haze may be less than or equal to about 2%, but the disclosure is not limited thereto.

The cover window CW may have a small thickness to minimize the weight of the display device 1 and may have high strength and hardness to protect the display panel DP from external impacts.

The optical functional layer OFL may be interposed between the cover window CW and the touch electrode layer TEL, and an adhesive member may be disposed between the optical functional layer OFL and the cover window CW. The adhesive member may be a photocured adhesive layer OCR including the resin composition as described above.

In an embodiment, as shown in FIG. 3B, the protective layer PL may be disposed on the cover window CW. The protective layer PL may cover the cover window CW and may protect the cover window CW. The protective layer PL may include at least one transparent synthetic resin such as polyethylene terephthalate (PET), polypropylene (PP), polystyrene (PP), and polyimide (PI), and may include a hard coating layer. In an embodiment, an adhesive member, such as a photocurable adhesive layer (not shown) including the resin composition, may be disposed between the protective layer PL and the cover window CW. In another embodiment, as shown in FIG. 3A, the protective layer PL may be omitted, and the outermost surface of the display device 1 may be provided as the cover window CW to improve the glass texture.

### EXAMPLES

### Preparation of Resin Composition

The resin compositions of Examples 1 to 5 and Comparative Examples 1 to 5 were prepared according to the composition ratios shown in Table 1 and Table 2, respectively. The composition ratio of each material refers to parts by weight based on the total weight of the composition (100 parts by weight).

Each material listed in Table 1 and Table 2 was stirred for 30 minutes at 1000 rpm at room temperature by using a planetary centrifugal mixer (Shashin Chemical Co., Ltd.) in a light-shielding container to obtain the resin compositions of Examples 1 to 5 and Comparative Examples 1 to 5.

TABLE 1

| | | Molecular | Example | Example | Example | Example | Example |
|---|---|---|---|---|---|---|---|
| Material | | weight | 1 | 2 | 3 | 4 | 5 |
| Urethane | UV-3700B | 38000 | 5 | 1 | 3 | 3 | — |
| acrylate | UV-3300B | 13000 | 5 | — | — | 3 | 3 |
| oligomer | UN-7700 | 20000 | — | — | 3 | — | 3 |
| Multi- | Viscoat#260 | 268 | 0.2 | 1 | 0.5 | 0.5 | 0.5 |
| functional | | | | | | | |
| acrylic | | | | | | | |
| monomer | | | | | | | |
| Mono- | IDAA | 212 | 29.8 | 28 | 30 | 39.5 | 49.5 |
| functional | IBXA | 208 | 20 | — | 29.5 | 20 | 10 |
| acrylic | FA-512AS | 248 | 20 | 40 | — | 30 | 20 |
| monomer | FA-512M | 262 | | | 20 | — | — |
| | THF-A | 156 | 18 | 20 | 10 | — | 10 |
| Hydrogen | Esacure | 515 | 1 | 5 | 2 | 2 | 2 |
| abstraction- | 1001M | | | | | | |
| type | | | | | | | |
| Photopolymerization | | | | | | | |
| initiator | | | | | | | |
| Tertiary | Omnirad | 193 | 1 | — | 2 | — | 2 |
| amine type | EDB | | | | | | |
| Hydrogen | OmniradEHA | 277 | — | 5 | — | 2 | — |
| donor | | | | | | | |

TABLE 2

| | | | Comparative | Comparative | Comparative | Comparative | Comparative |
|---|---|---|---|---|---|---|---|
| | | Molecular | Example | Example | Example | Example | Example |
| Material | | weight | 1 | 2 | 3 | 4 | 5 |
| Urethane | UV-3700B | 38000 | | 3 | 3 | 3 | 3 |
| Acrylate | UV-3300B | 13000 | 15 | 3 | 3 | 3 | 3 |
| oligomer | UN-7700 | 20000 | — | — | — | — | — |
| Multi- | Viscoat#260 | 268 | 0.2 | 2 | 0.5 | — | 0.5 |
| functional | | | | | | | |
| acrylic | | | | | | | |
| monomer | | | | | | | |
| Mono- | IDAA | 212 | 29.8 | 38 | 39.5 | 39.5 | 39.5 |
| functional | IBXA | 208 | 15 | 20 | 20 | 20 | 20 |
| acrylic | FA-512AS | 248 | 20 | 30 | — | 20 | 20 |
| monomer | FA-512M | 262 | — | — | — | — | — |
| | FA-513AS | 206 | — | — | 30 | — | — |
| | THF-A | 156 | 18 | — | — | 12 | 12 |
| Hydrogen | Esacure | 515 | 1 | 2 | 2 | 2 | — |
| abstraction- | 1001M | | | | | | |
| type | | | | | | | |
| Photopolymerization | | | | | | | |
| initiator | | | | | | | |
| Intramolecular | Omnirad | 418 | — | — | — | — | 2 |
| ring- | 819 | | | | | | |
| opening | | | | | | | |
| type | | | | | | | |
| Photopolymerization | | | | | | | |
| initiator | | | | | | | |
| Tertiary | Omnirad | 193 | 1 | — | — | — | — |
| amine type | EDB | | | | | | |
| Hydrogen | OmniradEHA | 277 | — | 2 | 2 | — | — |
| donor | | | | | | | |

### Information on Materials Used to Prepare Resin Compositions

### [Urethane Acrylate Oligomer]

UV-3700B: Urethane acrylate (Mitsubishi Chemical Co., Ltd.)

UV-3300B: Urethane acrylate (Mitsubishi Chemical Co., Ltd.)

UN-7700: Urethane acrylate (Negami Industries Co., Ltd.)

### [Multi-Functional Acrylic Monomer]

Viscoat #260:1,9-nonane diol diacrylate (Osaka Organic Chemical Industry Co., Ltd.)

### [Mono-Functional Acrylic Monomer]

IDAA: Isodecyl acrylate (Osaka Organic Chemical Industry Co., Ltd.) (CAS No. 1330-61-6)

IBXA: Isobornyl acrylate (Osaka Organic Chemical Industry Co., Ltd.) (CAS No. 5888-33-5)

FA-512AS: Dicyclopentenyl oxyethyl acrylate (Resonac Co., Ltd.)

FA-512M: Dicyclopentenyl oxyethyl (meth)acrylate (Resonac Co., Ltd.)

FA-513AS: Dicyclofentanyl acrylate (Resonac Co., Ltd.) THF-A: Tetrahydrofurfuryl acrylate (Kyoeisha Chemical Co., Ltd.)

### [Hydrogen Abstraction-Type Photoradical Polymerization Initiator]

ESACURE 1001M: 1-[4-(4-benzoyl phenyl sulphanyl)phenyl]-2-methyl-2-(4-methylphenylsulfonyl) propan-1-one (IGM Resins Co., Ltd.)

### [Intramolecular Cleavage Type Photoradical Polymerization Initiator]

Omnirad 819: Phenylbis(2,4,6-trimethylbenzoyl) phosphine oxide (IGM Resins Co., Ltd.)

### [Hydrogen Donor]

Omnirad EDB: Ethyl-4-(dimethylamino)-benzoate (IGM Resins)

Omnirad EHA: Ethyl hexyl-4-dimethyl aminobenzoate (IGM Resins)

### Physical Property Evaluation

The physical properties of the resin compositions of Examples 1 to 5 and Comparative Examples 1 to 5 were evaluated in the following manner. Results thereof are shown in Table 3 and Table 4 below, respectively.

### [Viscosity Measurement]

The viscosity of each of the resin compositions was measured at 30° C. and at a speed of 50 rpm using a viscometer (TVE-25L: Toki Sangyo) based on the JISK 2283 test method.

### [Inkjet Printer Application Characteristics]

Each of the resin compositions were applied on a slide glass and ultraviolet (UV) cured at a head temperature of 30° C. by using an inkjet printer from MICROJET Co., Ltd. The appearance of the coating film was evaluated after curing.

Evaluation results were expressed as follows.

⊚: Applicable with no thickness variation in the applied film

Δ: Applicable with thickness variation in the applied film

x: Not ejectable

### [Measurement of Cured Material Storage Modulus]

A release-treated PET film (NP100A, Panac Co., Ltd.) and a silicone rubber sheet (Tigers Polymer Co., Ltd.) with holes of 8 mm in diameter were sequentially laminated on a slide glass (Matsunami Glass Co., Ltd., S1112), and 28 μL of the resin composition was dropped into the holes of the silicone rubber sheet. In this regard, a UV LED lamp with emission peaks at 405 nm and at 365 nm was used to radiate UV rays so that the total amount of light (cumulative dose) was 4000 mJ/cm² to obtain a cured resin product sample with a diameter of 8 mm and a thickness of 500 μm. With respect to the obtained cured resin product sample, the storage modulus was measured using a dynamic viscoelasticity measurement device (Antonpa, MCR302) at 25° C., a frequency of 1 Hz, a temperature range of-50° C. to 80° C., and a temperature rise rate of 2° C./min.

[Appearance after Bonding of Hardened Material]

The resin composition was applied to a thickness of 200 μm on a slide glass (Matsunami Glass Co., Ltd., S1112) using an inkjet printer. In this regard, a UV LED lamp with emission peaks at 405 nm and at 365 nm was used to radiate ultraviolet rays so that the total amount of integrated light was 4000 mJ/cm², and a cured resin product layer was formed on a glass slide. A PET film (Toyobo Co., Ltd., product name A4360, 50 μm of thickness) was attached to the cured resin product layer, and was processed by using an automatic heating and pressing device (Chiyoda Electronics Co., Ltd., product name ACS-230) under the conditions of 30° C. and 0.5 MPa for 5 minutes. As a result, a laminate consisting of a slide glass, a cured material layer, and a PET film were obtained. The appearance of the obtained laminate was evaluated. Evaluation results were expressed as follows.

⊚: No unreacted material leakage or no non-bonded parts.

Leakage of unreacted materials: Leakage of uncured unreacted materials.

Poor bonding: There are areas where the slide glass and PET glass were not bonded.

### [Light Resistance Test]

A light resistance test was conducted on the laminate manufactured as described above to confirm the appearance after bonding the cured product. The light resistance test was conducted according to the DIN75220 standard by radiating UV rays with a wavelength of 280 nm to 300 nm at an intensity of 1,120 W/m² for 80 hours.

The yellow index (YI) of the laminate before and after the light resistance test was measured by using a spectroscopic colorimeter COH 7700 (Nippon Denshoku), and the corresponding ΔYI was calculated according to the following Equation 1.

$$Δ Y I = Y I after test - Y I before test \qquad [ Equation 1 ]$$

### [180° Peel Strength]

To confirm the appearance after bonding the cured product, the 180° peel strength of the laminate manufactured as described above was tested by using a tensile tester (INSTRON 5965). The 180° peel strength test was conducted at 25° C. and at a tensile speed of 300 mm/min.

TABLE 3

| | Exam- | Exam- | Exam- | Exam- | Exam- |
|---|---|---|---|---|---|
| | ple | ple | ple | ple | ple |
| Material | 1 | 2 | 3 | 4 | 5 |
| Viscosity [mPa · s] (30° C.) | 19.8 | 5.1 | 12.7 | 10.8 | 9.7 |
| Inkjet printer application | ⊚ | ⊚ | ⊚ | ⊚ | ⊚ |
| (30° C.) | | | | | |
| Storage modulus [MPa] | 0.132 | 0.487 | 0.395 | 0.228 | 0.052 |
| (25° C.) | | | | | |
| Appearance after bonding | ⊚ | ⊚ | ⊚ | ⊚ | ⊚ |
| ΔYI before and after light | 0.78 | 0.35 | 0.63 | 0.48 | 0.95 |
| resistance test | | | | | |
| 180° peel strength [gf/25 | 2780 | 3570 | 3250 | 2940 | 2600 |
| mm] (25° C.) | | | | | |

TABLE 4

| | Com- | Com- | Com- | Com- | Com- |
|---|---|---|---|---|---|
| | parative | parative | parative | parative | parative |
| | Exam- | Exam- | Exam- | Exam- | Exam- |
| | ple | ple | ple | ple | ple |
| material | 1 | 2 | 3 | 4 | 5 |
| Viscosity [mPa · s] | 21.8 | 13.9 | 13.4 | 12.3 | 12.1 |
| (30° C.) | | | | | |
| Inkjet printer | Not | ⊚ | ⊚ | ⊚ | ⊚ |
| application (30° C.) | ejectable | | | | |
| Storage modulus | 0.102 | 0.567 | 0.395 | 0.028 | 0.252 |
| [MPa] (25° C.) | | | | | |
| Appearance after | Unable to | Poor | ⊚ | Un- | Un- |
| bonding | evaluate | bonding | | reacted | reacted |
| | | | | product | product |
| | | | | Leakage | Leakage |
| AYI before and after | Unable to | 0.64 | 3.10 | 2.7 | 0.89 |
| light resistance test | evaluate | | | | |
| 180° peel strength | Unable to | 1980 | 2950 | 540 | 1500 |
| [gf/25 mm] (25° C.) | evaluate | | | | |

Referring to Table 3, the viscosity at 30° C. of each of the resin compositions of Examples 1 to 5 was in a range of about 5 mPa-s to about 20 mPa-s, making it possible to apply the resin compositions to a uniform thickness by using an inkjet printer at 30° C.

The storage modulus of each of the cured resin products obtained by curing the resin compositions of Examples 1 to 5 at 25° C. was in a range of about 0.05 MPa to about 0.5 MPa, indicating that the cured resin products had appropriate adhesiveness and cohesiveness at room temperature. The 180° peel strength of the adhesive with which the slide glass and PET film was bonded to the cured resin product showed a high value of over 2500 [gf/25 mm].

The cured resin product products obtained by curing the resin compositions of Examples 1 to 5 all had small ΔYI values of less than 1 before and after the light resistance test, showing little yellowing.

Compared to Examples 1 to 5, Comparative Example 1 has a high content of urethane acrylate oligomer, Comparative Example 2 has a high content of multi-functional acrylic monomer, Comparative Example 3 used a dicyclopentanyl group instead of a dicyclopentenyl group in a mono-functional acrylate monomer, Comparative Example 4 did not use a tertiary amine-type hydrogen donor, and Comparative Example 5 used an intramolecular ring-opening type photopolymerization initiator instead of a hydrogen abstraction-type photopolymerization initiator.

Referring to Table 4, the resin composition of Comparative Example 1 had high viscosity, and the ejection of the resin composition of the Comparative Example 1 into an inkjet printer was difficult at 30° C.

The cured resin product obtained by curing the resin composition of Comparative Example 2 had a high storage modulus at 25° C., and bonding defects occurred in the laminate. As a result, the adhesion to the slide glass and the PET film was decreased, and the 180° C. peel strength of the laminate was decreased.

The cured resin product obtained by curing the resin composition of Comparative Example 3 had a large ΔYI before and after the light resistance test, and yellowing progressed after the test.

The cured resin product obtained by curing the resin composition of Comparative Example 4 had a low storage modulus at 25° C., and for this reason, unreacted materials in the cured resin product overflowed to the outside when bonding the slide glass and the FET film together. The cohesion of the cured product was reduced, and the 180° peel strength was greatly reduced.

The cured resin product obtained by curing the resin composition of Comparative Example 5 was strongly affected by oxygen inhibition and the amount of unreacted materials was increased. For this reason, when the slide glass and the FET film were bonded, the unreacted material in the cured resin product overflowed to the outside. The 180° peel strength was greatly reduced due to poor curing of the adhesive surface.

Resin compositions according to an embodiment enable a stable inkjet process at room temperature, has high adhesive strength even after photocuring in an oxygen atmosphere, can prevent or reduce yellowing, and is applicable to display devices of various shapes.

The above description is an example of technical features of the disclosure, and those skilled in the art to which the disclosure pertains will be able to make various modifications and variations. Therefore, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A resin composition comprising:
about 1 part by weight to about 10 parts by weight of a urethane (meth)acrylate oligomer having two (meth)acrylic groups;
about 80 parts by weight to about 95 parts by weight of a mono-functional acrylate monomer;
about 0.1 parts by weight to about 1 part by weight of a (meth)acrylate monomer having two (meth)acrylic groups; and
about 1 part by weight to about 5 parts by weight of a hydrogen abstraction-type photoinitiator, wherein
some of the mono-functional acrylate monomer include a dicyclopentenyl group,
the parts by weight are based on a total weight of the resin composition, and
the resin composition has a viscosity of greater than or equal to about 5 mPa·s and less than 20 mPas at 30° C.

2. The resin composition of claim 1, wherein a weight average molecular weight (Mw) of the urethane (meth)acrylate oligomer having two (meth)acrylic groups is greater than or equal to about 10,000 and less than 40,000.

3. The resin composition of claim 1, wherein the resin composition comprises two or more types of the urethane (meth)acrylate oligomer having two (meth)acrylic groups.

4. The resin composition of claim 3, wherein a molecular weight difference between the two or more types of urethane (meth)acrylate oligomer having two (meth)acrylic groups is in a range of about 5,000 to about 30,000.

5. The resin composition of claim 1, wherein a weight average molecular weight (Mw) of the mono-functional acrylate monomer is less than or equal to about 500.

6. The resin composition of claim 1, wherein the resin composition comprises two or more types of the mono-functional acrylate monomer.

7. The resin composition of claim 1, wherein an amount of monomers having the dicyclopentenyl group from among the mono-functional acrylate monomer is in a range of about 20 parts by weight to about 40 parts by weight, based on the total weight of the resin composition.

8. The resin composition of claim 1, wherein a weight average molecular weight (Mw) of the (meth)acrylate monomer having two (meth)acrylic groups is less than or equal to about 500.

9. The resin composition of claim 1, wherein the resin composition does not include a solvent.

10. The resin composition of claim 1, further comprising:
about 1 part by weight to about 5 parts by weight of a tertiary amine group-containing hydrogen donor.

11. The resin composition of claim 1, wherein the urethane (meth)acrylate oligomer having two (meth)acrylic groups comprises UV-3700B (Mitsubishi Chemical), UV-3300B (Mitsubishi Chemical), UN-7700 (Negami Industry), UF-C051 (Kyoeisha Chemical), CN9021NS (SARTOMER), KRM9465 (Daicel-Allnex), EBECRYL8411 (Daicel-Allnex), or a combination thereof.

12. The resin composition of claim 1, wherein the mono-functional acrylate monomer comprises isodecyl acrylate, isobornyl acrylate, tetrahydrofurfuryl (meth)acrylate, dicyclopentenyl oxyethyl acrylate, dicyclopentenyl oxyethyl (meth)acrylate, 2-ethylhexyl acrylate, 4-hydroxybutyl acrylate, 2-methyl-2-ethyl-1,3-dioxolane-4-ylmethyl acrylate, butyl acrylate, lauryl acrylate, 2-ethyl hexyl diglycol acrylate, mono(2-acryloyloxyethyl) succinate, tert-butyl acrylate, n-octyl acrylate, cyclohexyl acrylate, or a combination thereof.

13. The resin composition of claim 1, wherein the (meth)acrylate monomer having two (meth)acrylic groups comprises 1,9-nonanedioldiacrylate, 1,4-butanedioldi(meth)acrylate, 1,3-butyleneglycoldi(meth)acrylate, 1,6-hexanedioldi(meth)acrylate, 1,8-octanedioldi(meth)acrylate, 1,9-octanedioldiacrylate, 1,12-dodecanedioldi(meth)acrylate, neopentylglycoldi(meth)acrylate, dicyclopentanyldi(meth)acrylate, cyclohexane-1,4-methanoldi(meth)acrylate, tricyclodecanedimethanoldi(meth)acrylate, dicyclopentanedimethyloldi(meth)acrylate, neopentylglycol modified trimethylpropanedi(meth)acrylate, adamantanedi(meth)acrylate, trimethylolpropanetri(meth)acrylate, or a combination thereof.

14. The resin composition of claim 1, wherein a storage modulus at 25° C. of a cured resin product produced after photocuring of the resin composition is greater than or equal to about 0.05 MPa and less than 0.5 MPa.

15. The resin composition of claim 1, wherein a change in yellow index (ΔYI) of a cured resin product produced after photocuring of the resin composition, before and after a light resistance test based on a DIN75220 standard, is less than or equal to about 1.

16. The resin composition of claim 1, wherein a 180° peel strength at 25° C. of a laminate obtained by bonding a polyethylene telephthalate (PET) film and soda lime glass by using the resin composition is in a range of about 2500 (gf/25 mm) to about 5000 (gf/25 mm).

17. A cured resin product manufactured by photocuring the resin composition of claim 1.

18. The cured resin product of claim 17, wherein the cured resin product is an adhesive member.

19. A display device comprising:
a display panel;
a cover window disposed on the display panel; and
a photocured adhesive layer arranged between the display panel and the cover window, wherein
the photocured adhesive layer comprises the cured resin product of claim 17.

20. The display device of claim 19, wherein the display device is a foldable display device.
